(19) United States
(12) Patent Application Publication
(10) Pub. No.: US 2024/0276888 A1
(43) Pub. Date: Aug. 15, 2024

(54) TOPOLOGICAL TUNNEL JUNCTION

(71) Applicant: International Business Machines Corporation, Armonk, NY (US)

(72) Inventors: Alan Molinari, Kilchberg (CH); Heinz Schmid, Waedenswil (CH); Bogdan Cezar Zota, Rüschlikon (CH); Bernd W. Gotsmann, Horgen (CH)

(21) Appl. No.: 18/109,596

(22) Filed: Feb. 14, 2023

(51) Int. Cl. H10N 50/10; H10B 61/00; H10N 50/01; H10N 50/85

(52) U.S. Cl. CPC H10N 50/10; H10B 61/00; H10N 50/01; H10N 50/85

(57) ABSTRACT

A tunnel junction including a layer stack, wherein the layer stack comprises a first contact layer, a first topological layer extending on top of the first contact layer, an electrically insulating layer extending on top of the first topological layer, a second topological layer extending on top of the electrically insulating layer, a free ferromagnetic layer extending on top of the second topological layer, and a second contact layer extending on top of the free ferromagnetic layer. Each of the first topological layer and the second topological layer includes a topological material. The first topological layer, the electrically insulating layer, and the second topological layer are engineered to exhibit a variation of magnetoresistance and a variation of intervalley scattering upon changing a magnetic state of the free ferromagnetic layer. The disclosure is further directed to related devices and methods of operation.

### STATEMENT REGARDING FEDERALLY SPONSORED RESEARCH OR DEVELOPMENT

The project leading to this application has received funding from the European Union's Horizon 2020 research and innovation program under the InNaTo (contract N. 898113) and SCHINES (contract N. 829044) grant agreement.

### BACKGROUND

The present disclosure relates generally to the field of tunnel junctions and, more specifically, to a tunnel junction comprising a layer stack including layers of topological materials. Accordingly, the tunnel junction is often referred to as a “topological tunnel junction.”

Magnetic tunnel junctions (MTJs) are the basic building blocks of several types of memory devices, including read-and-write heads of hard disk drives, toggle magnetoresistive random access memories (toggle MRAMs) and spin-transfer torque MRAMs (STT MRAMs).

To date, one of the main challenges with MTJ architectures is to maintain a high signal-to-noise ratio, correlated to a large magnetoresistance (MR) ratio, and thermal stability, without increasing the resistance area (RA) product of the devices for energy efficiency.

However, the materials currently used in conventional MTJs do not allow to overcome technological limits in terms of MR ratio and thermal stability, let alone issues in terms of energy efficiency and storage density.

### SUMMARY

An embodiment of the present disclosure includes a tunnel junction including a layer stack, wherein the layer stack comprises a first contact layer, a first topological layer extending on top of the first contact layer, an electrically insulating layer extending on top of the first topological layer, a second topological layer extending on top of the electrically insulating layer, a free ferromagnetic layer extending on top of the second topological layer, and a second contact layer extending on top of the free ferromagnetic layer. Each of the first topological layer and the second topological layer includes a topological material. The first topological layer, the electrically insulating layer, and the second topological layer are engineered to cause a variation of magnetoresistance and a variation of intervalley scattering upon changing a magnetic state of the free ferromagnetic layer

Another embodiment of the present disclosure includes a device comprising one or more tunnel junctions as described above. Each tunnel junction is connected in the device via its first contact layer and its second contact layer.

Another embodiment of the present disclosure includes a method of operating a tunnel junction. The method first comprises providing a tunnel junction as described above. A first magnetic field is applied to the free ferromagnetic layer to change a resistance state of the tunnel junction from a first resistance state to a second state. Next, a second magnetic field is applied to the free ferromagnetic layer to change the resistance state of the tunnel junction from the second resistance state to a further resistance state that is substantially identical to the first resistance state. The first magnetic field is preferably applied so as to generate an interfacial magnetic exchange field causing intervalley scattering, which impacts the overall resistance state of the tunnel junction.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 illustrates a 3D view of a device involving a plurality of topological tunnel junctions, where the device is configured as a field magnetoresistive random-access memory device in which illustrative embodiments of the present disclosure may be implemented.

FIG. 2 illustrates a topological tunnel junction, i.e., an electronic device including a layer stack involving layers of topological materials, in accordance with embodiments of the present disclosure.

FIGS. 3A and 3B illustrate are 2D cross-sectional views illustrating the operation of a first type of topological tunnel junction, in accordance with embodiments of the present disclosure.

FIGS. 4A and 4B illustrate 2D cross-sectional views illustrating the operation of a second type of topological tunnel junction, in accordance with embodiments of the present disclosure.

FIG. 5 illustrates a flow diagram of high-level steps of a method of operating a topological tunnel junction, in accordance with embodiments of the present disclosure.

While the embodiments described herein are amenable to various modifications and alternative forms, specifics thereof have been shown by way of example in the drawings and will be described in detail. It should be understood, however, that the particular embodiments described are not to be taken in a limiting sense. On the contrary, the intention is to cover all modifications, equivalents, and alternatives falling within the spirit and scope of the disclosure.

### DETAILED DESCRIPTION

Aspects of the present disclosure relate to the field of tunnel junctions, and more particularly to a tunnel junction comprising a layer stack including layers of topological materials. While the present disclosure is not necessarily limited to such applications, various aspects of the disclosure may be appreciated through a discussion of various examples using this context.

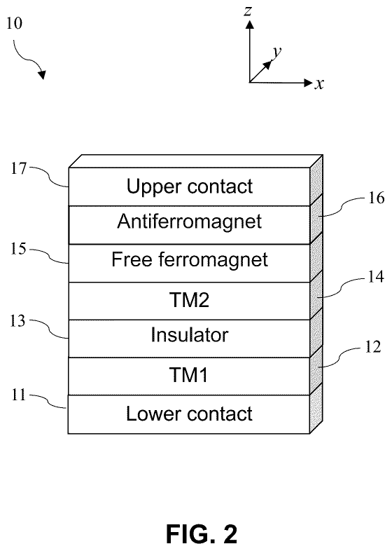

A first aspect of the present disclosure is now described in detail, in reference to FIGS. 2-4B. This aspect concerns a tunnel junction 10. The junction 10 includes a stack of layers (or layer stack) that are successively arranged along a stacking direction, which is assumed to be the direction z in the accompanying drawings.

As shown in FIG. 2, the layer stack includes (from bottom to top): a first contact layer 11, a first topological layer 12, an electrically insulating layer 13, a second topological layer 14, a free ferromagnetic layer 15, and a second contact layer. Such layers are successively arranged from bottom to top in FIG. 2. That is, the first topological layer 12 extends on top of the first contact layer 11. The electrically insulating layer 13 extends on top of the first topological layer 12. The second topological layer 14 extends on top of the electrically insulating layer 13. The free ferromagnetic layer 15 extends on top of the second topological layer 14, and the second contact layer 17 extends on top of the free ferromagnetic layer 15.

That a given layer extends on top of another layer means that the top layer extends above the bottom layer, so as to form successive (but not necessarily consecutive) layers. That is, the top layer may possibly coat the bottom layer and thus be in direct contact therewith, as in preferred embodiments. However, intermediate layers may possibly be involved. For example, an antiferromagnetic layer 16 is optionally provided between the free ferromagnetic layer 15 and the top contact layer, as assumed in FIG. 2. However, this layer 16 is optional. In addition, or in variants, ultrathin bonding layers may possibly be required between any two successive layers mentioned above.

Remarkably, two layers 12, 14 of the stack include a topological material. Such layers are referred to as the first topological layer 12 and the second topological layer 14. So, the junction 10 involves layers 12, 14 of topological materials and can thus be referred to as a “topological tunnel junction” (TTJ) or a “magnetic topological tunnel junction”, the working principle of which relies on intervalley scattering and differs from a conventional magnetic tunnel junction (MTJ). Namely, the first topological layer 12, the electrically insulating layer 13, and the second topological layer 14, are engineered (i.e., designed and processed) to exhibit both magnetoresistance and intervalley scattering upon suitably changing a magnetic state of the free ferromagnetic layer 15.

Topological materials are materials that can support a flow of electrons on their surface (i.e., in a superficial region close to the surface), thanks to topologically protected surface states. Surface states of topological materials are said to be topologically protected as a result of topological properties of such materials. Such properties are known per se; they are highly dependent on the dimensions of such materials and their symmetries. Topological protection means the system cannot spontaneously and continuously break its topological properties, which offers protection to the charge carriers against scattering events. This protection ensures low electrical resistivity through the topological material.

The present tunnel junction concept relies on a novel type of tunnel junction, i.e., a TTJ that has a multilayer heterostructure involving layers 12, 14 of topological materials TM1 and TM2. The layers 12, 14 are arranged on opposite sides of a layer of a conventional electrical insulator 13, i.e., an insulating tunnel barrier. Moreover, the two topological layers 12, 14 are capped by a free ferromagnetic layer 15 on top. The antiferromagnetic layer 16 can optionally be provided to serve as a pinning layer for the free ferromagnetic layer 15.

In embodiments, the topological layers 12 and 14 are electrically conducting topological materials with bulk electronic band structures characterized by linear energy-momentum dispersion relations (i.e. topological cones) crossing in topological nodes in proximity of the Fermi energy. In particular, the topological layers 12 and 14 can be made of 3D topological semimetals, including Dirac semimetals (DSMs), Weyl semimetals (WSMs) and related topological variants. Examples of potentially suitable 3D topological semimetals and variants comprise type-1 WSMs (e.g., NbAs, NbP, TaAs), type-2 WSMs (e.g., WP₂, MoP₂, WTe₂, MoTe₂, TalrTe₄), magnetic Weyl semimetals (e.g., PrAlGe, Co₂MnGa, Co₃Sn₂S₂, Mn₃Sn, Mn₃Ge), topological chiral semimetals containing multifold fermions (e.g., CoSi, RhSi), and nodal line semimetals (e.g., Ag₂S, Co₂MnGa, ZrSiS, HfSiS, PbTaSe₂). A further possibility is to use 2D van der Waals topological materials, such as graphene and transition metal dichalcogenides MX₂ (where M=W or Mo, and X=Te, S, Se, or MnBi₂Te₄). Plus, 2D and 3D topological materials may possibly be combined, so a variety of topological materials, and combinations thereof, can be contemplated.

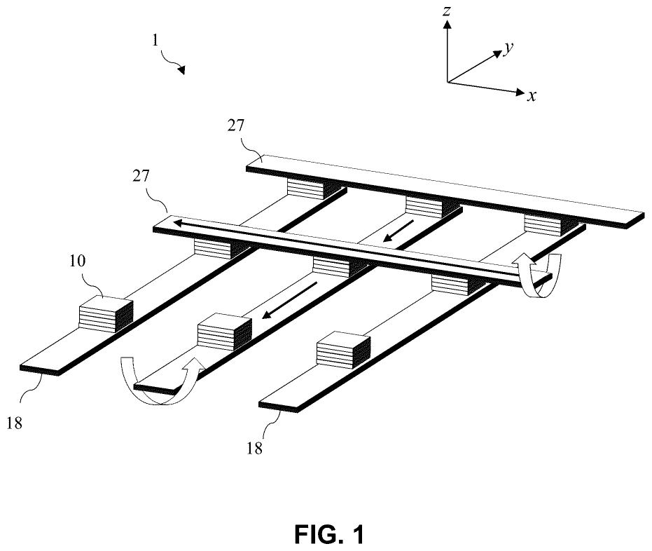

The tunnel junction 10 may possibly form part of a larger device 1 (shown in FIG. 1), as described later in detail, in reference to another aspect of the present disclosure. The present tunnel junctions 10 and devices 1 can be regarded as valleytronics devices, to the extent that the layer stack of the tunnel junction is designed so as to be subject to intervalley scattering, which phenomenon impacts the tunnel magnetoresistance response of the junction.

In fact, the total ON/OFF magnetoresistance ratio of the tunnel junction 10 is determined by two contributions, which respectively relate to intervalley scattering (as occurring between the topological layers 12, 14) and the intrinsic variation of magnetoresistance in the second topological layer 14. Both contributions are triggered by the magnetic exchange field generated by the free ferromagnetic layer 15 and perceived by the topological layer 14 via magnetic proximity effect. Remarkably, the combination of such phenomena (i.e., magnetoresistance and intervalley scattering) that can be achieved with a layer stack as discussed above can overcome the magnetoresistance (MR) ratio limits of conventional MTJ architectures (which rely on usual magnetic materials).

In more detail, in the tunnel junction 10 as described above, a large ON/OFF magnetoresistance ratio can be achieved by optimizing intervalley scattering and the intrinsic magnetoresistance. Intervalley scattering can be enhanced by increasing the strength of the interfacial exchange field, which, in turn, promotes the separation of the topological cones in the momentum space (or k-space) in the second topological layer 14. Suitable combinations of topological materials can be contemplated to enhance intervalley scattering, where such materials can be suitably selected based on their topological band structures.

A strong interfacial exchange field is desired because this also induces a larger variation of magnetoresistance in the second topological layer 14. The variation of magnetoresistance in the second topological layer 14 can be extremely large. For instance, use can be made of 3D topological Weyl semimetal, such as NbP, to achieve remarkable magnetoresistance modulations of about 100% between 200-300 K, by applying a magnetic field of about 1 T. Such a design can achieve a MR ratio as high as 850000% at 1.85 K and 9 T. In variants, 2D topological materials can be used, such as graphene, the variation of magnetoresistance can be of the order of 100-1000% at room temperature for an applied magnetic field of about 2 T.

Upon applying a magnetic field (i.e., magnetizing the free ferromagnetic layer 15), an interfacial magnetic exchange field is generated, which results in a shift of the topological cones (e.g., Dirac/Weyl cones) of TM2 in the momentum space, or k-space. For instance, a Dirac semimetal can undergo a topological phase transition and turn into a Weyl semimetal upon application of an external magnetic field. As said, the proposed TTJ design is subject to the phenomenon of intervalley scattering, i.e., a scattering of charge carriers tunneling from TM1 to TM2, to the extent that their topological cones are separated in the k-space. This results in a current tunneling through the insulating layer of the TTJ device, which, in turn, determines the ON/OFF resistance states.

Furthermore, the proposed TTJ design is more energy efficient than conventional MTJ designs. First, the proposed design allows a lower resistance area (RA) product to be achieved. While conventional conductors undergo an increase in resistivity upon scaling their size down to the nanoscale, topological materials exhibit the opposite behavior due to the contribution of conducting surface states. Second, the proposed TTJ design requires lower currents for writing bits.

In detail, in a conventional MTJ device, an external current flowing through word and bit lines is employed to generate a magnetic field. This, in turn, causes to flip the orientation of the spins of the free ferromagnetic layer and thus also its remanent magnetization between opposite states, i.e., +MR and −MR states. Instead, a TTJ as proposed herein relies on the adjustment of the magnetization of the free ferromagnetic layer 15 between the magnetized and demagnetized states only, i.e., the MR- and 0-magnetization states. Such magnetized/demagnetized states in a TTJ can be achieved by sending current pulses through word and bit lines (see FIG. 1) having lower amplitude and/or duration, compared to conventional MTJ devices. In particular, the demagnetized state (0-magnetization state) is ideally achieved when a current pulse is set to flip only half of the spins of the free ferromagnetic layer 15. Basically, it is not required to achieve the 0-magnetization state in an absolute sense, i.e. involving exactly the same amounts of opposite spins. The important point is that the variation of magnetic exchange field generated by the free magnetic layer 15 between the magnetized and demagnetized states produces a sizeable shift (in the k-space) of the topological cones of the second topological layer 14. Note, the magnetized and demagnetized states are normally stable over time, therefore the TTJ can be regarded as a non-volatile device.

Another advantage of the proposed TTJ design is its enhanced thermal stability. In general, the alignment of the spins in magnetic materials is sensitive to thermal fluctuations. The topological protection of topological materials allows them to be more stable against thermal fluctuations. Plus, since the proposed solution requires lower writing currents and offer a higher thermal stability, it further allows the storage density of bits of information to be increased.

The following describes particularly preferred embodiments of the present disclosure. To start with, the topological material of one or each of the first topological layer 12 and the second topological layer 14 is preferably a Dirac topological semimetal or a Weyl topological semimetal. For example, the topological material of the second topological layer 14 can be a Dirac topological semimetal that is able to undergo a topological phase transition to a Weyl topological semimetal upon adequately magnetizing the free ferromagnetic layer 15 for it to pass from a demagnetized state to a magnetized state. The topological material of the first topological layer 12 can be a Dirac topological semimetal or a Weyl topological semimetal too. However, the first topological layer 12 is typically engineered so as not to undergo any topological phase transition when magnetizing the free ferromagnetic layer 15 for it to pass from its demagnetized state to its magnetized state. I.e., the material of the layer 12 is chosen, dimensioned, and processed, so as not to undergo any topological phase transition upon magnetizing the layer 15.

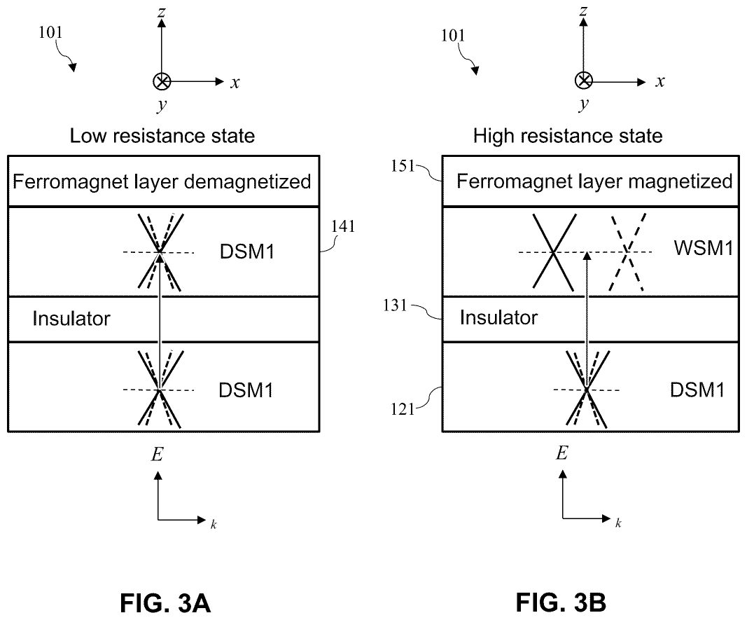

A first class of embodiments is now described in reference to FIGS. 3A and 3B, which depict 2D cross-sections of the layer stack of a tunnel junction 101, onto which schematic band structure plots in the energy—momentum plane (E, k) are overlaid. I.e., schematic depictions of the relevant topological cones are depicted to ease the interpretation of the underlying phenomena. The low resistance state and the high resistance state of the tunnel junction 101 respectively correspond to the demagnetized state and the magnetized state of the free ferromagnetic layer 151.

In this class of embodiments, the topological material of the first topological layer 121 is a Dirac topological semimetal (denoted by DSM1). Again, the topological layers 121, 141 are arranged on opposite sides of a layer 131 of a conventional electrical insulator, i.e., an insulating tunnel barrier. Moreover, the layers 121-141 are capped by a free ferromagnet 151 on top.

The topological material of the second topological layer 141 is chosen so as to have a phase corresponding to a Dirac topological semimetal (DSM1, FIG. 3A) in the low resistance state of the tunnel junction 101. In that case, the topological material of the second topological layer 141 is chosen so as to undergo a topological phase transition to a Weyl topological semimetal (WSM1, FIG. 3B) upon suitably magnetizing the free ferromagnetic layer 151 for it to pass from its demagnetized state (corresponding to the low resistance state of the junction) to its magnetized state (corresponding to the high resistance state of the junction).

In the low resistance state (FIG. 3A), tunneling occurs without intervalley scattering between the bottom DSM1 layer and the top DSM1 layer, and carriers have a same momentum before and after tunneling. Here, none of the topological layers 121, 141 shows any magnetoresistance; the ferromagnetic layer is demagnetized, so the ferromagnetic layer does not generate any interfacial magnetic exchange field.

In the high resistance state (FIG. 3B), the magnetic field applied causes a phase transition from DSM1 to WSM1. Notice the separation of the Weyl cones in WSM1. The available charge states in k-space are different before and after tunneling in that case. In detail, here the ferromagnetic layer is magnetized, so it generates an interfacial magnetic exchange field that is felt by the top topological layer 141, now turned into WSM1. Both intervalley scattering and magnetoresistance occur in that case. Intervalley scattering occurs in relation to the tunneling of charge carriers between the bottom topological layer (DSM1) 121 and the top topological layer (WSM1) 141. Magnetoresistance is related to the intrinsic variation of resistance in the top layer 141 layer due to the presence of an interfacial magnetic exchange field generated by the top topological layer 141. Several combinations of topological materials can be contemplated. For example, each of the first topological layer 121 and the second topological layer 141 may include Cd₃As₂, Na₃Bi, or ZrTe₅. Still, the topological layers 121 and 141 are preferable made of the same topological material, which is why the material of the topological layers 141 is also denoted by DSM1 in FIG. 3A. This, in principle, should enhance the ON/OFF ratio, because in the ON state the overlap of cones in k-space is maximum, which configuration gives rise to the lowest possible intervalley scattering.

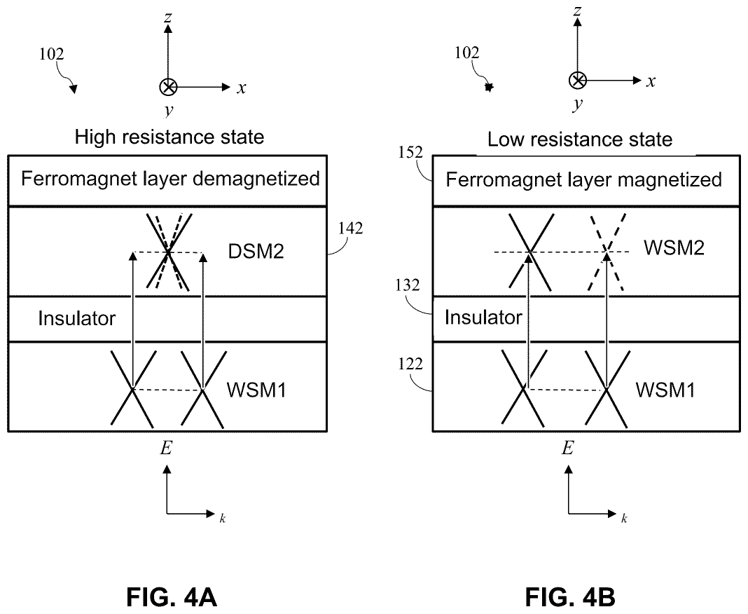

FIGS. 4A and 4B illustrate a second class of embodiments, involving another type of tunnel junction 102, wherein the topological material of the first topological layer 122 is a Weyl topological semimetal. Unlike the tunnel junction 101, here the low resistance state and the high resistance state of the tunnel junction 102 respectively correspond to the magnetized state and the demagnetized state of the free ferromagnetic layer 152. Again, the topological layers 122, 142 are arranged on opposite sides of a layer 132 of a conventional electrical insulator, and are capped by a free ferromagnet 152 on top.

The topological material of the first topological layer 122 can be chosen as a Weyl topological semimetal (WSM1). However, the topological material of the second topological layer 142 is now chosen to have a phase corresponding to a Weyl topological semimetal (WSM2) in the low resistance state of the tunnel junction 102. In this case, the topological material of the second topological layer 142 is chosen so as to undergo a topological phase transition from a Dirac topological semimetal (DSM2, FIG. 4A) to a Weyl topological semimetal (WSM2, FIG. 4B) upon magnetizing the free ferromagnetic layer 152 for it to pass from its demagnetized state to its magnetized state.

In the high resistance state (FIG. 4A), tunneling occurs with intervalley scattering and carriers have a different momentum before and after tunneling. Note, here intervalley scattering occurs as the ferromagnetic layer is demagnetized, while the top topological layer (DSM2) 142 does not show magnetoresistance because the ferromagnetic layer does not generate any interfacial magnetic exchange field.

In the low resistance state (FIG. 4B), the magnetic field applied transforms DSM2 into WSM2. The separation of the Weyl cones in WSM2 favors the conditions of an overlap between pockets of carriers in k-space. The available charge states are different before and after tunneling, although they may possibly have a similar momentum. Magnetoresistance occurs as the ferromagnetic layer is magnetized. Intervalley scattering is less pronounced than in FIG. 4A, because now the topological cones of the top topological layer (WSM2, previously DSM2) are shifted in k-space and show a better overlap with the pockets of the bottom topological layer (WSM1) 122. The larger the overlap in k-space of the pockets of the bottom topological layer 122 (WSM1) and the top topological layer 142 (WSM2), the lower the intervalley scattering related to tunneling.

Again, several combinations of topological materials can be contemplated. However, here the first topological layer 122 and the second topological layer 142 have different chemical compositions. For example, the topological material of the first topological layer 122 may include NbAs, Ag₂S, NbP, TaAs, or WP₂. Meanwhile, the topological material of the second topological layer 142 may include one Cd₃As₂, Na₃Bi, or ZrTe₅.

More generally, other topological materials can be involved. For example, another class of embodiments may combine 3D topological materials (beyond Dirac and Weyl semimetals) and/or 2D topological materials. In general, the first topological layer 12 and the second topological layer 14 may have different chemical compositions. I.e., the chemical compositions substantially differ, whereby different chemical elements, or different proportions of such elements, are involved in the topological layers. In principle, however, the topological materials may also differ in terms of dopant amounts, provided that the dopant amounts substantially differ.

The first class of embodiments (as illustrated in FIGS. 3A, 3B) is generally preferred to the second class of embodiments (FIGS. 4A, 4B), because the former will likely result in a larger ON/OFF resistance ratio. In the first class of embodiments, both intervalley scattering and magnetoresistance effects effectively contribute to the total ON/OFF resistance ratio (the two effects are cumulative). In the second class of embodiments, intervalley scattering and magnetoresistance are not cumulative; they even work against each other in this case. Intervalley scattering is expected to dominate, though this strongly depends on the choice of topological materials and the details of their electronic band structures.

Referring back to FIG. 2, the electrically insulating layer 13 typically includes a usual electrical insulator, such as MgO, Al₂O₃, TiO₂, or SiO₂. The free ferromagnetic layer 15 may notably include one of CoFeB, Co, CoFe, and Co₂MnSi. The contact layers are made of electrically conducting materials, e.g., similar to contact layers of conventional MTJs. Additional materials (not shown) may be involved, e.g., in a substrate supporting the structure or in a material embedding the layer stack.

In terms of structural properties, the successive layers shown in FIG. 2 are preferably arranged consecutively. I.e., in that case, the electrically insulating layer 13 directly coats the first topological layer 12, the second topological layer 14 directly coats the electrically insulating layer 13, and the free ferromagnetic layer 15 directly coats the second topological layer 14.

The average in-plane dimension of the stack will typically be larger than 50×50 nm². The first topological layer 12 preferably has an average thickness of 3 to 15 nm, while the average thickness of the second topological layer 14 is preferably between 1 and 4 nm. Similarly, the average thickness of the electrically insulating layer 13 is preferably between 1 and 4 nm. In general the thickness of each topological layer should be chosen in such a way to avoid crosstalk between top and bottom Fermi surface states, as this can cause electron back-scattering, and thus an increase in resistance.

In particular, the thickness of the second topological layer 14 should preferably be chosen in such a way that the interfacial magnetic exchange field generated by the free ferromagnetic layer 15 is strong enough to induce a sizeable shift (in the k-space) of the topological energy-momentum cones in the second topological layer 14.

The magnetic exchange field produced by proximity effect can be as large as tens of Tesla in the vicinity of the interface between the second topological layer 14 and the free ferromagnetic layer 15, though its magnitude quickly decreases into the second topological layer 14 already after a few nanometers.

The electrically insulating layer 13 has to be thin enough to permit the tunneling of carriers between the first topological layer 12 and the second topological layer 14. The tunneling process between the topological layers 12 and 14 may possibly involve bulk topological states and surface states. The electrically insulating layer 13 also acts as a spacer to minimize the possible residual magnetic exchange field felt by the first topological layer 12.

Referring now to FIG. 1, according to another aspect, the present disclosure can be embodied as a device 1 comprising one or more TTJs 10 as described above in reference to the first aspect of the present disclosure. In the example of FIG. 1, the device 1 includes several TTJs 10, which are interconnected in the device via their respective first contact layer 11 and second contact layer 17, see FIG. 2. Each of the TTJs 10 may for instance be configured as a field magnetoresistive random-access memory element, as assumed in FIG. 1.

The memory device 1 shown in FIG. 1 includes pairs of word and bit lines 18, 27, which are coupled via TTJs 10, whereby the first contact layer 11 of a TTJ is in contact with layer 18, while the second contact layer 17 of this TTJ 10 is in contact with layer 27. Note, the layers 18, 27 may also play the role of contact layers 11, 17. Perpendicular lines 18, 27 are used to apply a magnetic field. In FIG. 1, the straight arrows represent electrical current flowing through the word and bit lines, while the curved arrows denote the generated magnetic field.

For reading, a probing current is applied through a TTJ, which allows to read a low resistance state or a high resistance state. For writing, two current paths from the word and bit lines 18, 27 combine their effect to create an external magnetic field sufficiently strong to flip the magnetization in the free ferromagnetic layer of the TTJ.

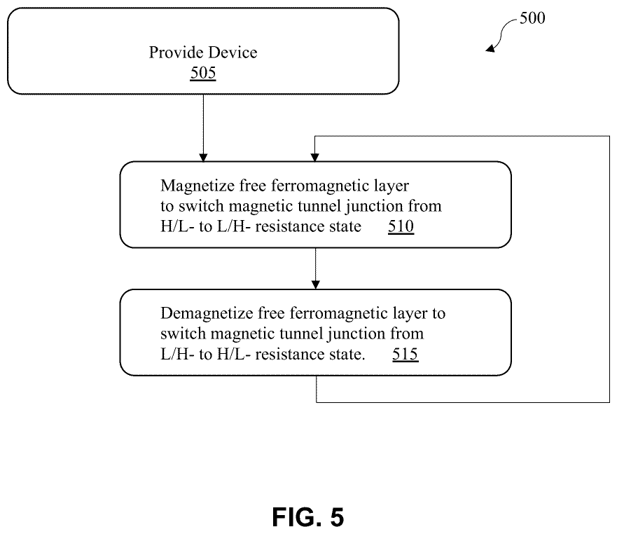

According to a final aspect, the present disclosure can also be embodied as a method 500 of operating a TTJ 10 as described earlier. As shown in FIG. 5, the TTJ 10 is provided at step 505. In embodiments, the TTJ is operated by successively applying magnetic fields. A first magnetic field is applied to the free ferromagnetic layer 15 to change a resistance state of the TTJ 10 from a first resistance state to a second state. This is illustrated at step 510. Next, a second magnetic field is applied to the free ferromagnetic layer 15 to change the resistance state of the TTJ 10 from the second resistance state to a further resistance state that is substantially identical to its first resistance state. This is illustrated at step 515. The TTJ is typically operated cyclically, like an MTJ.

In practice, in a device 1 such as shown in FIG. 1, the magnetic field generated by the word and bit lines causes to magnetize the free ferromagnetic layer of each junction 10. Once magnetized, the free ferromagnetic layer generates an interfacial magnetic field in the second topological layer, which causes a shift of the topological cones in k-space. In turn, such a shift may increase the intervalley scattering (as in the first class of embodiments described earlier) or decrease the intervalley scattering (second class of embodiments) of the carriers that tunnel between the two topological layers.

Note, the magnetic field applied at step 510 is preferably chosen to magnetize the free ferromagnetic layer 15, so as to generate an interfacial magnetic exchange field causing a variation of intervalley scattering, which impacts an overall resistance state of the tunnel junction. In particular, the magnetic field applied at step 510 can be calibrated to result in a variation of intervalley scattering causing a scattering of charge carriers from the first topological layer 12 to the second topological layer 14, which impacts the overall resistance state of the tunnel junction. That is, by suitably magnetizing the ferromagnetic layer, an interfacial magnetic exchange field is generated, which allows to induce a shift of Dirac/Weyl cones (in k-space) in TM2. As explained earlier, the tunneling current through the TTJ device 10 defines the ON/OFF resistance states based on the phenomenon of intervalley scattering (i.e., a scattering of charge carriers from TM1 to TM2, assuming that their topological cones are well separated in the k-space) and the change in magnetoresistance experienced by TM2.

While the present disclosure has been described with reference to a limited number of embodiments, variants, and the accompanying drawings, it will be understood by those skilled in the art that various changes may be made, and equivalents may be substituted without departing from the scope of the present disclosure. In particular, a feature (device-like or method-like) recited in a given embodiment, variant or shown in a drawing may be combined with or replace another feature in another embodiment, variant or drawing, without departing from the scope of the present disclosure. Various combinations of the features described in respect of any of the above embodiments or variants may accordingly be contemplated, that remain within the scope of the appended claims. In addition, many minor modifications may be made to adapt a particular situation or material to the teachings of the present disclosure without departing from its scope. Therefore, it is intended that the present disclosure is not limited to the particular embodiments disclosed, but that the present disclosure will include all embodiments falling within the scope of the appended claims. In addition, many other variants than explicitly touched above can be contemplated. For example, other materials than those explicitly mentioned may be contemplated, whether for the topological layers or the other layers of the TTJs.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used and logical, mechanical, electrical, and other changes may be made without departing from the scope of the various embodiments. In the previous description, numerous specific details were set forth to provide a thorough understanding the various embodiments. But, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present disclosure has been described in terms of specific embodiments, it is anticipated that alterations and modification thereof will become apparent to the skilled in the art. Therefore, it is intended that the following claims be interpreted as covering all such alterations and modifications as fall within the true spirit and scope of the disclosure.

What is claimed is:

1. A tunnel junction including a layer stack, wherein the layer stack comprises:
a first contact layer;
a first topological layer extending on top of the first contact layer;
an electrically insulating layer extending on top of the first topological layer;
a second topological layer extending on top of the electrically insulating layer;
a free ferromagnetic layer extending on top of the second topological layer; and
a second contact layer extending on top of the free ferromagnetic layer,
wherein each of the first topological layer and the second topological layer includes a topological material, and
wherein the first topological layer, the electrically insulating layer, and the second topological layer, are engineered to cause a variation of magnetoresistance and a variation of intervalley scattering upon changing a magnetic state of the free ferromagnetic layer.

2. The tunnel junction according to claim 1, wherein the topological material of one or each of the first topological layer and the second topological layer is one of a Dirac topological semimetal or a Weyl topological semimetal.

3. The tunnel junction according to claim 1, wherein the topological material of the second topological layer is a Dirac topological semimetal that is able to undergo a topological phase transition to a Weyl topological semimetal upon magnetizing the free ferromagnetic layer for it to pass from a demagnetized state to a magnetized state.

4. The tunnel junction according to claim 1, wherein the topological material of the first topological layer is one of a Dirac topological semimetal or a Weyl topological semimetal, the first topological layer engineered so as not to undergo a topological phase transition upon magnetizing the free ferromagnetic layer for it to pass from the demagnetized state to the magnetized state.

5. The tunnel junction according to claim 1, wherein the topological material of the first topological layer is a Dirac topological semimetal, the tunnel junction has a low resistance state and a high resistance state, respectively corresponding to the demagnetized state and the magnetized state of the free ferromagnetic layer, and the topological material of the second topological layer is such as to have a phase corresponding to a Dirac topological semimetal in the low resistance state of the tunnel junction.

6. The tunnel junction according to claim 5, wherein the topological material of each of the first topological layer and the second topological layer includes one of Cd3 As2, Na3Bi, or ZrTe5.

7. The tunnel junction according to claim 4, wherein the topological material of the first topological layer is a Weyl topological semimetal, the tunnel junction has a low resistance state and a high resistance state, respectively corresponding to the magnetized state and the demagnetized state of the free ferromagnetic layer, and the topological material of the second topological layer is such as to have a phase corresponding to a Weyl topological semimetal in the low resistance state of the tunnel junction.

8. The tunnel junction according to claim 7, wherein the topological material of the first topological layer includes one of NbAs, Ag2S, NbP, TaAs, or WP2, and the topological material of the second topological layer includes one of Cd3As2, Na3Bi, or ZrTe5.

9. The tunnel junction according to claim 1, wherein the layer stack further includes an antiferromagnetic layer extending on top of the free ferromagnetic layer, between the free ferromagnetic layer and the second contact layer.

10. The tunnel junction according to claim 1, wherein the electrically insulating layer directly coats the first topological layer, the second topological layer directly coats the electrically insulating layer, and the free ferromagnetic layer directly coats the second topological layer.

11. The tunnel junction according to claim 1, wherein the electrically insulating layer includes one of MgO, Al2O3, TiO2, or SiO2.

12. The tunnel junction according to claim 1, wherein the free ferromagnetic layer includes one of CoFeB, Co, CoFe, or Co₂MnSi.

13. The tunnel junction according to claim 1, wherein the first topological layer and the second topological layer of the tunnel junction have different chemical compositions.

14. The tunnel junction according to claim 1, wherein the first topological layer has an average thickness of 3 to 15 nm, the second topological layer has an average thickness of 1 to 4 nm, and an average thickness of the electrically insulating layer is between 1 and 4 nm.

15. A device comprising:
one or more tunnel junctions, wherein each of the one or more tunnel junctions includes:
a layer stack, comprising:
a first contact layer;
a first topological layer extending on top of the first contact layer;
an electrically insulating layer extending on top of the first topological layer;
a second topological layer extending on top of the electrically insulating layer;
a free ferromagnetic layer extending on top of the second topological layer; and
a second contact layer extending on top of the free ferromagnetic layer,
wherein:
each of the first topological layer and the second topological layer includes a topological material,
the first topological layer, the electrically insulating layer, and the second topological layer, are engineered to cause a variation of magnetoresistance and a variation of intervalley scattering upon changing a magnetic state of the free ferromagnetic layer; and
the one or more tunnel junctions are connected in the device via its first contact layer and its second contact layer.

16. The device according to claim 15, wherein the device includes a plurality of tunnel junctions, and the tunnel junctions are interconnected in the device via their respective first contact layer and second contact layer.

17. The device according to claim 16, wherein each tunnel junction of the plurality of tunnel junctions is configured as a field magnetoresistive random-access memory element.

18. A method of operating a tunnel junction comprising:
providing a tunnel junction that includes a layer stack comprising a first contact layer, a first topological layer extending on top of the first contact layer, an electrically insulating layer extending on top of the first topological layer, a second topological layer extending on top of the electrically insulating layer, a free ferromagnetic layer extending on top of the second topological layer, and a second contact layer extending on top of the free ferromagnetic layer, wherein each of the first topological layer and the second topological layer includes a topological material;
applying a first magnetic field to the free ferromagnetic layer to change a resistance state of the tunnel junction from a first resistance state to a second state; and
applying a second magnetic field to the free ferromagnetic layer to change the resistance state of the tunnel junction from the second resistance state to a further resistance state that is substantially identical to the first resistance state.

19. The method according to claim 18, wherein the first magnetic field is applied to magnetize the free ferromagnetic layer and accordingly generate an interfacial magnetic exchange field causing a variation of intervalley scattering, which impacts an overall resistance state of the tunnel junction.

20. The method according to claim 19, wherein the intervalley scattering causes a scattering of charge carriers from the first topological layer to the second topological layer.
